(19) United States
(12) Patent Application Publication
(10) Pub. No.: US 2013/0078821 A1
(43) Pub. Date: Mar. 28, 2013

(54) IMPRINT METHOD, IMPRINT APPARATUS, AND MANUFACTURING METHOD OF SEMICONDUCTOR DEVICE

(71) Applicant: Yohko FURUTONO, Kanagawa (JP)

(72) Inventor: Yohko FURUTONO, Kanagawa (JP)

(21) Appl. No.: 13/418,030

(22) Filed: Mar. 12, 2012

(30) Foreign Application Priority Data
Sep. 22, 2011 (JP) 2011-208113

(51) Int. Cl. H01L 21/312; B29C 59/16

(52) U.S. Cl. 438/780; 425/174.4; 264/447; 257/E21.24

(57) ABSTRACT

In an imprint method according to embodiments, light that hardens a resist is irradiated to a light irradiation region near an alignment mark in order to prevent the resist from being filled in the alignment mark of a template, when the alignment process between the template and a substrate is performed. After the alignment process is completed, the resist is filled in the template pattern and the alignment mark, and then, light that hardens the resist is irradiated onto the template.

### CROSS-REFERENCE TO RELATED APPLICATIONS

This application is based upon and claims the benefit of priority from Japanese Patent Application No. 2011-208113, filed on Sep. 22, 2011; the entire contents of which are incorporated herein by reference.

### FIELD

Embodiments described herein relate generally to an imprint method, an imprint apparatus, and a manufacturing method of a semiconductor device.

### BACKGROUND

There is a pattern forming method using an imprint as one of methods for forming a pattern on a substrate. During the imprint, a template having formed thereon grooves of a desired pattern is pressure-bonded to an UV curing resin applied onto a substrate to be processed. The UV curing resin is hardened by an exposure with the template and the UV curing resin being in intimate contact with each other, whereby the pattern is formed (a template pattern is transferred) on the UV curing resin on the substrate to be processed.

The refractive index of the template and the refractive index of the UV curing resin are close to each other. Therefore, in the imprint method described above, when a resist is filled in an alignment mark portion, the alignment mark cannot be confirmed, which entails a problem of misalignment.

Even when the resist is not applied to the alignment mark portion, the resist that spreads from the pattern portion during the contact process and filling process goes into the alignment portion, resulting in that the alignment mark becomes invisible. Therefore, it is desired to prevent the resist from going into the alignment mark during the alignment.

### BRIEF DESCRIPTION OF THE DRAWINGS

FIG. 1 is a view illustrating a configuration of an imprint apparatus according to a first embodiment;

FIG. 2 is a top view illustrating a configuration of a template;

FIG. 3 is a view illustrating an imprint shot on a wafer;

FIG. 4 is a view for describing an outline of an alignment process;

FIGS. 5A to 5C are views for describing a procedure of an imprint process according to the first embodiment;

FIG. 6 is a view illustrating a resist distribution in an alignment;

FIGS. 7A and 7B are views for describing an UV light irradiation region that includes only a part of an alignment mark;

FIGS. 8A to 8C are views for describing an UV light irradiation region that does not include the alignment mark;

FIGS. 9A to 9C are views for describing the UV light irradiation region and a movement of the resist;

FIG. 10 is a view illustrating a configuration of an imprint apparatus according to a second embodiment;

FIGS. 11A to 11C are views illustrating a structure of an aperture;

FIG. 12 is a view illustrating an UV light irradiation region according to a third embodiment; and

FIG. 13 is a view illustrating the UV light irradiation region on a wafer.

### DETAILED DESCRIPTION

In general, according to one embodiment, an imprint method is provided. In the imprint method, a resist is dropped onto a substrate having a first alignment mark. Then, an alignment process is performed between the first alignment mark and a second alignment mark, which is formed on a template, while filling the resist into a template pattern of the template by a press-contact of the template pattern to the resist on the substrate. With this alignment process, the template is aligned to a predetermined position on the substrate. During the alignment process, light that hardens the resist is irradiated to a light irradiation region near the second alignment mark in order to prevent the resist from being filled in the second alignment mark, whereby the resist in the light irradiation region is hardened. After the alignment process, the resist is filled in the template pattern and the second alignment mark with the template being kept aligned on the predetermined position on the substrate. Thereafter, light that hardens the resist is irradiated to the template.

Exemplary embodiments of the imprint method, an imprint apparatus, and a manufacturing method of a semiconductor device will be explained below in detail with reference to the accompanying drawings. The present invention is not limited to the following embodiments.

### First Embodiment

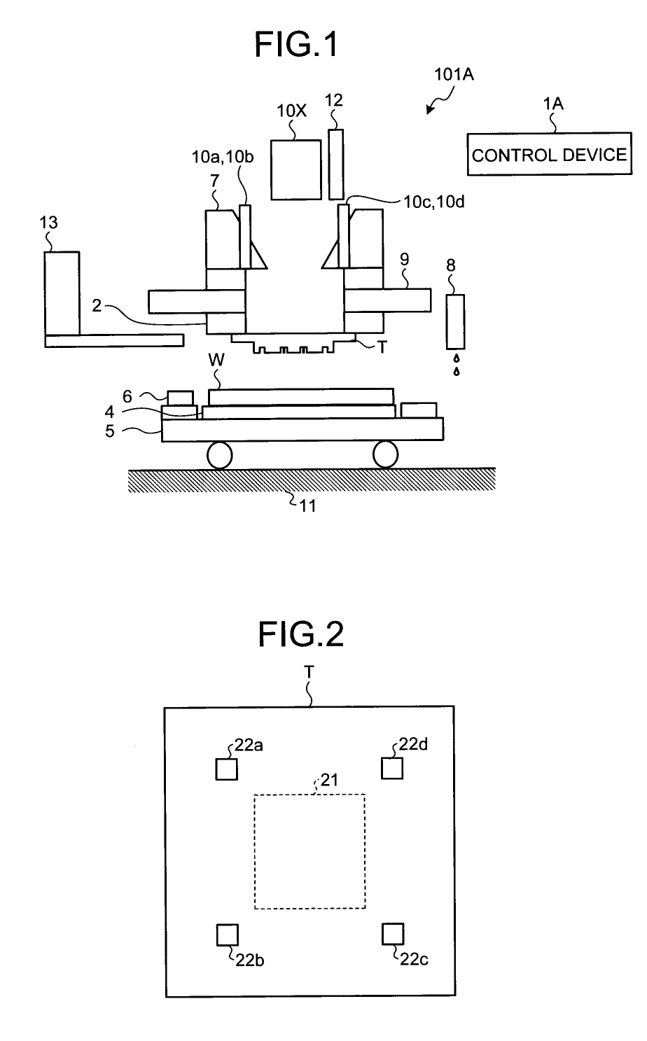

FIG. 1 is a view illustrating a configuration of an imprint apparatus according to a first embodiment. An imprint apparatus 101A transfers a template pattern (circuit pattern, etc.) of a template (original plate) T onto a substrate on which the pattern is to be transferred (substrate to be processed) such as a wafer W.

The imprint apparatus 101A according to the present embodiment completes an alignment of the template T to an imprint shot on the wafer W before a resist (transfer material) is filled into an alignment mark formed on the template T.

The imprint apparatus 101A irradiates UV light to the alignment mark formed on the template T and its surrounding during the alignment, in order to harden the resist near the alignment mark. In other words, during a process of spreading the resist onto the wafer W, light having a wavelength of hardening the resist is irradiated to the region where the resist has not yet spread, whereby the resist is hardened.

With this process, the time until the resist is filled into the alignment mark on the template T is delayed, and the alignment is completed before the resist is filled into the alignment mark on the template T. After the alignment, the imprint apparatus 101A fills the resist into the alignment mark on the template T.

The imprint apparatus 101A includes a control device 1A, an original-plate stage 2, a substrate chuck 4, a sample stage 6, a reference mark 6, an alignment sensor 7, a liquid dropping device (dropping unit) 8, a stage base 9, an UV light source (second light irradiation unit) 10X, a plate stage 11, a CCD (charge coupled device) camera 12, an original-plate conveyance arm 13, and UV light sources (first light irradiation unit) 10a to 10d.

The plate stage 11 has a major surface in a horizontal direction, and the sample stage 5 moves onto the major surface. The sample stage 5 has the wafer W placed thereon, and moves in a plane (horizontal plane) parallel to the placed wafer W. When a resist 40 serving as a transfer material is dropped onto the wafer W, the sample stage 5 moves the wafer W to the portion below the liquid dropping device 8. On the other hand, when an imprint process to the wafer W is carried out, the sample stage 5 moves the wafer W to the portion below the template T.

The template T has formed thereon grooves (irregularities) of a desired pattern as a template pattern. The template T is made of a material that transmits light (UV light) having a wavelength of hardening UV curing resin.

The substrate chuck 4 is mounted on the sample stage 5. The substrate chuck 4 fixes the wafer W onto a predetermined position on the sample stage 5. The reference mark 6 is formed on the sample stage 5. The reference mark 6 is for detecting the location of the sample stage 5, and is used for loading the wafer W onto the sample stage 5.

The stage base 9 supports the template T, and presses the template pattern on the template T against the resist (later-described resist 40) on the wafer W. The stage base 9 moves in the vertical direction, thereby pressing (imprinting) the template T onto the resist 40 and separating (releasing) the template T from the resist 40.

The original-plate stage 2 is provided on the bottom surface (near the wafer W) of the stage base 9. The original-plate stage 2 fixes the template T onto a predetermined position by a vacuum contact from the backside (the surface on which the template pattern is not formed) of the template T.

The alignment sensor 7 is mounted on the stage base 9. The alignment sensor 7 detects the position of the alignment mark (later-described alignment marks 32a to 32d) formed on the wafer W and the alignment mark (later-described alignment marks 22a to 22d) formed on the template T. When the template T is aligned to the imprint shot on the wafer W, the position of the sample stage 5, having the wafer W placed thereon, is controlled in order that the alignment marks 22a to 22d on the template T and the alignment marks 32a to 32d on the wafer W are superimposed, respectively.

The liquid dropping device 8 drops the resist 40 onto the wafer W. The resist 40 is, for example, UV curing resin. The liquid dropping device 8 is an ink-jet type, for example.

The UV light source 10X is a light source that irradiates UV light, and is mounted above the stage base 9. After the resist 40 is filled into the template pattern or the alignment marks 22a to 22d, the UV light source 10X irradiates the UV light on the whole surface of the imprint shot from above the template T with the template T being pressed against the resist 40.

The UV light sources 10a to 10d are light sources that irradiate the UV light onto a predetermined region on the template T (on the imprint shot) in a pinpoint manner. The UV light sources 10a to 10d respectively irradiate the UV light to the alignment marks 22a to 22d, formed on the template T, and their surroundings.

In the present embodiment, the UV light sources 10a to 10d irradiate the light, having the wavelength of hardening the UV curing resin, onto the region that encloses the alignment marks 22a to 22d and where the UV curing resin has not yet spread. With this process, the UV curing resin is hardened on the boundary between the UV curing resin and the UV light irradiation region by the UV light sources 10a to 10d, before the resist 40 serving as the UV curing resin spreads over the alignment marks 22a to 22d, whereby a wall of the resist 40 is formed.

The CCD camera 12 images the resist 40, which is being filled in the template pattern on the template T, through the nearly transparent template T. The CCD camera 12 is provided above the stage base 9.

The original-plate conveyance arm 13 conveys the template T in the imprint apparatus 101A. The original-plate conveyance arm 13 conveys the template T, which is carried in from the outside of the imprint apparatus 101A, to the position of the original-plate stage 2.

The control device 1A controls the original-plate stage 2, the substrate chuck 4, the sample stage 5, the alignment sensor 7, the liquid dropping device 8, the stage base 9, the UV light source 10X, the plate stage 11, the CCD camera 12, the original-plate conveyance arm 13, and the UV light sources 10a to 10d.

The control device 1A in the present embodiment drops the resist 40 on a predetermined position on the imprint shot in order to prevent the resist 40 from going into the alignment marks 22a to 22d during the alignment process and to allow the resist 40 to go into the alignment marks 22a to 22d after the alignment process.

The resist 40 is dropped on the wafer W beforehand upon performing the imprint to the wafer W. Thereafter, the wafer W is moved to the portion immediately below the template T. The template pattern is then pressed against the resist 40 on the wafer W, while irradiating the UV light to the alignment marks 22a to 22d and their surroundings. With this process, the resist 40 is started to be filled into the template pattern, and the alignment of the template T to the wafer W is started.

During when the template pattern is pressed against the resist 40, the resist 40 (the resist 40 getting close to the alignment marks) in the UV light irradiation region is hardened. After the alignment is completed, the resist 40 is filled into the alignment marks 22a to 22d. After the resist 40 is filled into the template pattern and the alignment marks 22a to 22d, the UV light is irradiated to the whole surface of the template T, whereby all resists 40 are hardened. Then, the template T is removed from the resist 40. Thus, a transfer pattern corresponding to the template pattern is patterned onto the wafer W.

Next, the alignment process of the template T to the wafer W will be described. The alignment marks 22a to 22d on the template T will firstly be described. FIG. 2 is a top view illustrating the structure of the template. The template T has formed on its central region a template pattern forming region 21 of almost a rectangular shape, and the alignment marks 22a to 22d at the outside of the template pattern forming region 21.

The template pattern forming region 21 is a region where the template pattern such as a circuit pattern is formed. Each of the alignment marks 22a to 22d has a rectangular shape, for example, and is arranged in a vicinity of a corner of the template pattern forming region 21.

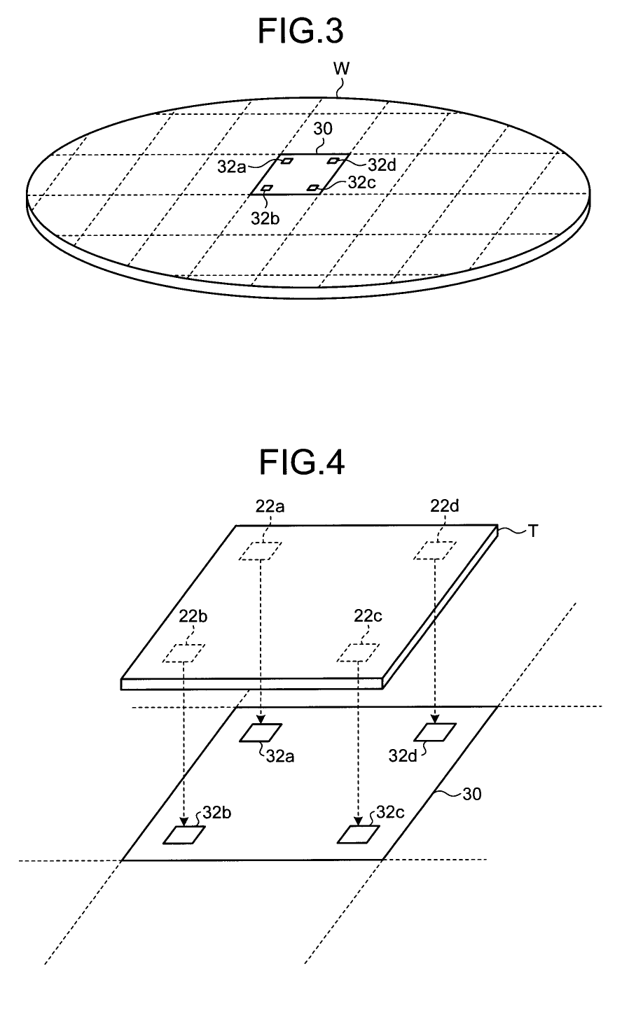

FIG. 3 is a view illustrating the imprint shot on the wafer. Plural imprint shots 30 are formed on the wafer W. The alignment marks 32a to 32d are formed on each of the imprint shots.

FIG. 4 is a view for schematically describing the alignment process. When the template T is aligned to the imprint shot 30, the alignment process is carried out such that the alignment marks 32a to 32d formed on the imprint shot 30 and the alignment marks 22a to 22d formed on the template T are superimposed.

Here, the alignment mark 32a is superimposed on the alignment mark 22a, and the alignment mark 32b is superimposed on the alignment mark 22b. Also, the alignment mark 32c is superimposed on the alignment mark 22c, and the alignment mark 32d is superimposed on the alignment mark 22d.

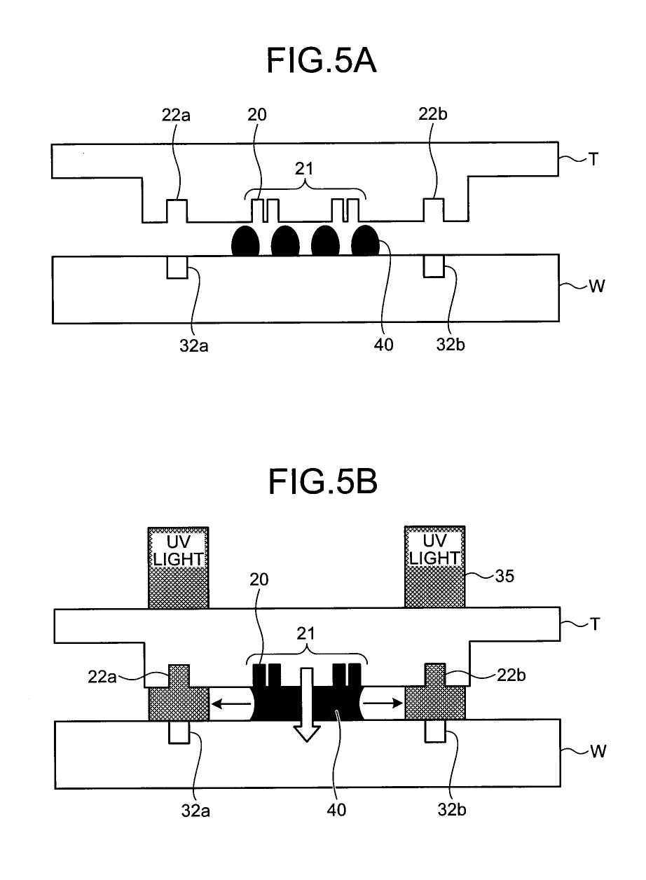

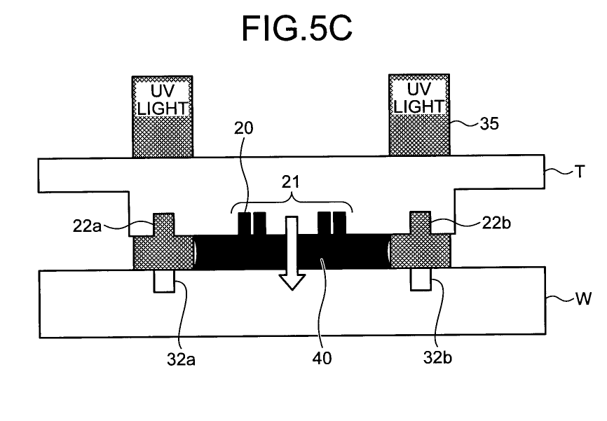

The imprint process according to the first embodiment will next be described. FIGS. 5A to 5C are views for describing a procedure of the imprint process according to the first embodiment. These figures are sectional views when the template T (wafer W) is cut along a line linking the alignment marks 22a and 22b (a line linking the alignment marks 32a and 32b).

As illustrated in FIG. 5A, the resist 40 is dropped onto the shot of the wafer W where the imprint is carried out. The resist 40 is dropped in plural droplets on the region of the wafer W where the template pattern 20 (template pattern forming region 21) is pressed.

Then, the UV light 35 is irradiated from the UV light sources 10a to 10d to the alignment marks 22a to 22d (alignment marks 32a to 32d) and their surroundings. FIG. 5B illustrates the case where the UV light is irradiated to the alignment marks 22a and 22b (alignment marks 32a and 32b) and their surroundings.

The template T is aligned to the wafer W with the irradiation of the UV light to the alignment marks 22a to 22d. The template T is aligned with the template T being pressed against the wafer W. Therefore, as illustrated in FIG. 5C, the resist 40 is filled in concave portions of the template pattern 20 during the alignment of the template T. In this case, the resist 40 at the outside of the template pattern forming region 21 spreads toward the alignment marks 22a to 22d. FIG. 5B illustrates the case where the resist 40 spreads toward the alignment marks 22a and 22b.

When the resist 40 reaches the UV light irradiation region as spreading toward the alignment marks 22a to 22d, it is hardened by the UV light 35. This can prevent the resist 40 from going into the alignment marks 22a to 22d during the alignment process. The resist 40 that is hardened during the alignment process is only some of the resist 40 around each of the alignment marks 22a to 22d. In other words, only some resist 40 is hardened in order to prevent the alignment marks 22a to 22d from being enclosed by the hardened resist 40.

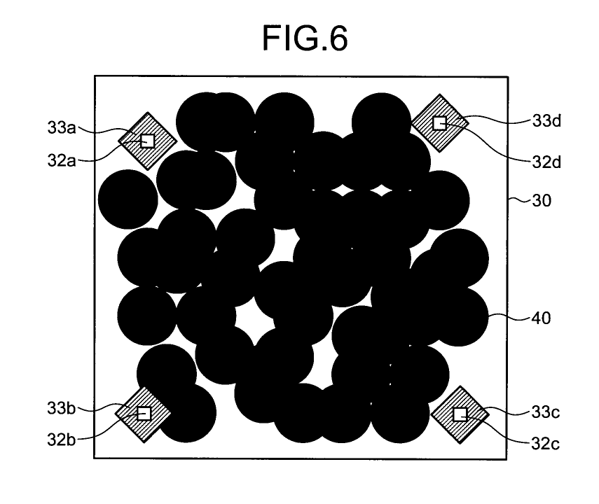

FIG. 6 is a view illustrating the resist distribution during the alignment process. FIG. 6 is a top view of the imprint shot 30 during the alignment process. The template T is not illustrated in FIG. 6. As illustrated in FIG. 6, the UV light is irradiated to the alignment marks 32a to 32d and their surroundings during the alignment process. Specifically, the UV light is irradiated to an UV light irradiation region 33a, whereby the UV light is irradiated to the alignment mark 32a and its surroundings. Similarly, the UV light is irradiated to the alignment marks 32b, 32c, and 32d and their surroundings by irradiating the UV light to UV light irradiation regions 33b, 33c, and 33d. Each of the UV light irradiation regions 33a to 33d includes each of the alignment marks 32a to 32d, and it is wider than each of the alignment marks 32a to 32d.

There is no chance that the resist 40 goes into the alignment marks 22a to 22d on the alignment marks 32a to 32d during the alignment process, since the UV light is irradiated to the UV light irradiation regions 33a to 33d during the alignment process.

After the alignment is completed, the irradiation of the UV light is stopped. Even after the irradiation of the UV light is stopped, the resist 40 is continuously filled into the template pattern 20. The resist 40, which is not hardened, near the alignment marks 22a to 22d is filled into the concave portion of the alignment marks 22a to 22d. After the resist 40 is completely filled in the template pattern 20, and the alignment marks 22a and 22b, the UV light is irradiated to the whole surface of the template T by the UV light source 10X. With this process, all resist 40 between the template T and the wafer W is hardened.

Thereafter, the template T is removed from the wafer W (mold release). Thus, the resist pattern corresponding to the template pattern 20 is formed on the wafer W. The resist pattern corresponding to the alignment marks 22a and 22b is formed on the alignment marks 32a to 32d.

The UV light irradiation regions 33a to 33d may include only a part of the respective alignment marks 32a to 32d. The UV light irradiation regions 33a to 33d may not include the respective alignment marks 32a to 32d.

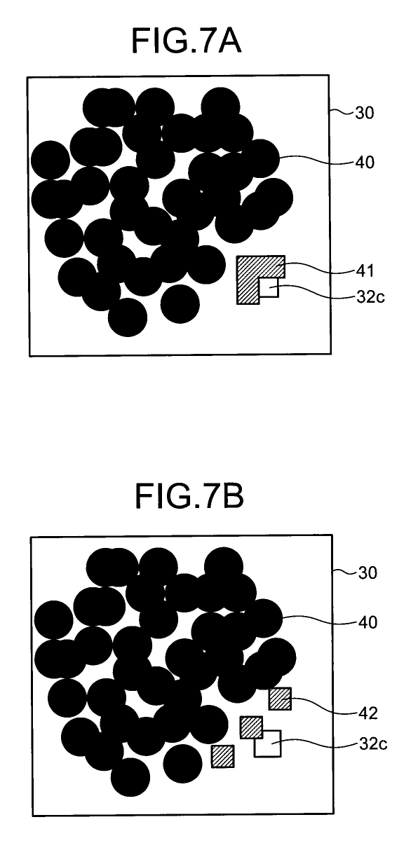

FIG. 7A and FIG. 7B are views for describing an UV light irradiation region in case where the UV light irradiation region contains only a part of the alignment mark. FIGS. 7 and 7B are top views of the UV light irradiation region. Since the similar UV light irradiation region is set on the alignment marks 32a to 32d, the UV light irradiation region set on the alignment mark 32c will be described here.

As illustrated in FIG. 7A, an L-shaped UV light irradiation region 41 may be arranged on the alignment mark 32c. The UV light irradiation region 41 is set so as to be overlapped with a part of the alignment mark 32c where the resist 40 enters.

As illustrated in FIG. 7B, plural (here, three) UV light irradiation regions 42 may be arranged on the alignment mark 32c. The UV light irradiation regions 42 are set so as to be overlapped with a part of the alignment mark 32c where the resist 40 enters.

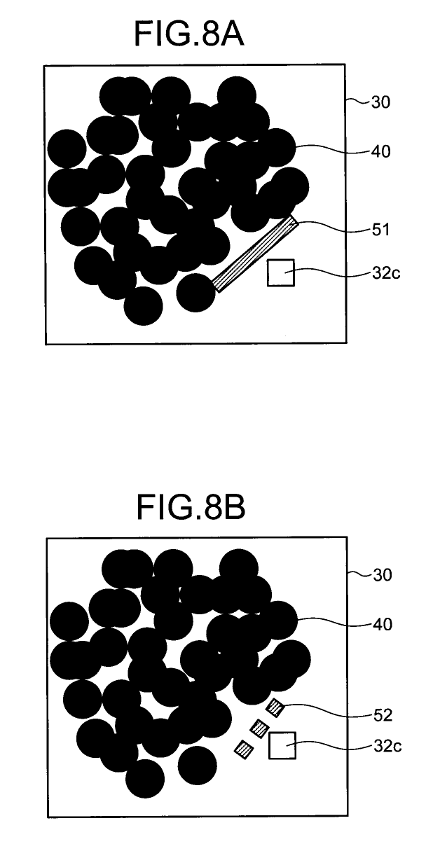

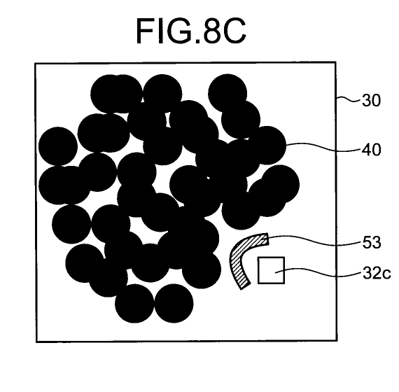

FIGS. 8A to 8C are views for describing an UV light irradiation region where the UV light irradiation region does not contain the alignment mark. FIGS. 8A to 8C are top views of the UV light irradiation region. Since the similar UV light irradiation region is set on the alignment marks 32a to 32d, the UV light irradiation region set on the alignment mark 32c will be described here.

As illustrated in FIG. 8A, a line-type UV light irradiation region 51 having a predetermined width and predetermined length may be arranged on the alignment mark 32c. As illustrated in FIG. 8B, plural (here, three) UV light irradiation regions 52 may be arranged on the alignment mark 32c. As illustrated in FIG. 8C, a C-shaped UV light irradiation region 53 that is bent at a predetermined angle may be arranged on the alignment mark 32c.

The UV light irradiation regions 51 to 53 are arranged between the alignment mark 32c and the region where the resist 40 is arranged. The UV light irradiation regions 51 to 53 are regions that are not overlapped with the alignment mark 32c.

As illustrated in FIGS. 6 to 8C, since the UV light irradiation regions 32a to 32d, 41, 42, and 51 to 53 (hereinafter sometimes referred to as UV light irradiation region X) are arranged, some resist 40 getting close to the alignment marks 22a to 22d is hardened on the UV light irradiation regions 32a to 32d, 41, 42, and 51 to 53. Therefore, the resist 40 has to go around the hardened resist 40 to the alignment marks 22a to 22d, in order to allow the resist 40 to fill in the alignment marks 22a to 22d.

In the present embodiment, the arrangement position of the resist 40 and the UV light irradiation region X are adjusted in order that the resist 40 goes into the alignment marks 22a to 22d after the alignment is completed.

For example, the position and shape of the UV light irradiation region X are set based upon at least one of various imprint conditions. The imprint conditions include, for example, a type of the resist 40, a drop amount of the resist 40, a drop position of the resist 40, viscosity of the resist 40, temperature of the resist 40, environment (temperature, humidity, pressure, etc.) in the imprint apparatus 101A, positions of the alignment marks 22a to 22d, time taken for the alignment, time taken from the completion of the alignment to the completion of resist filling, and imprint pressure (pressing force) applied to the template T upon the imprint. Various imprint conditions may be set based upon the UV light irradiation region X. For example, the drop amount and drop position of the resist 40 may be set based upon the UV light irradiation region X.

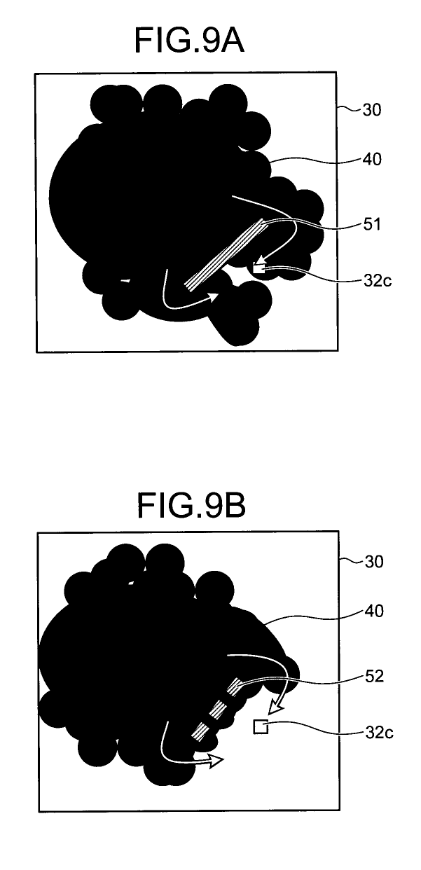

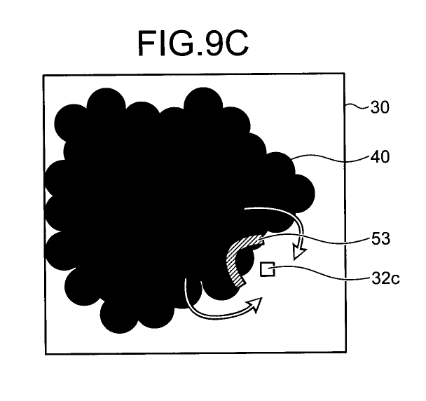

FIGS. 9A to 9C are views for describing the UV light irradiation region and the movement of the resist. FIGS. 9A to 9C illustrate the movement of the resist 40 on the UV light irradiation regions 51 to 53 illustrated in FIGS. 8A to 8C.

When the template pattern on the template T is imprinted on the wafer W, the resist 40 spreads in the imprint shot 30. With this, the resist 40 is filled in the template pattern, and the resist 40 also spreads over the position where the droplets of the resist 40 are not placed.

As illustrated in FIG. 9A, the resist 40 is hardened on the UV light irradiation region 51, so that the movement of the resist 40 that is likely to get close to the alignment mark 32c is blocked. As illustrated in FIG. 9B, the resist 40 is hardened on the UV light irradiation region 52, so that the movement of the resist 40 that is likely to get close to the alignment mark 32c is blocked. As illustrated in FIG. 9C, the resist 40 is hardened on the UV light irradiation region 53, so that the movement of the resist 40 that is likely to get close to the alignment mark 32c is blocked.

Thereafter, before the resist 40 goes around the alignment mark 32c, the alignment process is carried out, and then, the resist 40 reaches the alignment mark 32c. The present embodiment describes the case where the resist 40 is completely hardened in the UV light irradiation region. However, the resist 40 may be half-hardened to a predetermined hardness.

After the resist 40 is hardened in a part of the UV light irradiation region, the irradiation of the UV light may be stopped. Even in this case, some resist 40 is hardened, so that the resist 40, which is to be filled in the alignment marks 22a to 22d, goes into the alignment marks 22a to 22d around the hardened resist 40.

The resist 40 is not limited to the UV curing resin. A resin that is hardened by a wavelength other than the UV light may be used. Even in this case, the light having the wavelength that can cure the resist 40 is irradiated to the resist 40.

As described above, in the present embodiment, the imprint is carried out with the UV light being irradiated to some regions where the resist 40 has not yet been filled during the filling process of the resist 40. Therefore, the resist 40, which spreads due to the press-contact of the template T to the wafer W, is hardened in the UV light irradiation region X before it goes into the alignment marks 22a to 22d. Accordingly, the filling of the resist 40 into the alignment marks 22a to 22d can be delayed, which can prevent the resist 40 from going into the alignment marks 22a to 22d during the alignment process. Consequently, the present embodiment can provide the effect of being capable of delaying the time until the resist 40 is filled into the alignment marks 22a to 22d, and the effect of being capable of securing the pattern region close to the alignment marks 22a to 22d.

The position where the resist 40 is not dropped is set as the UV light irradiation region X so as to harden the resist 40 going into the UV light irradiation region X. This structure can prevent the resist 40 from going out of the UV light irradiation region X before the resist 40 is hardened.

Since the UV light irradiation region X is set based upon the imprint condition, the UV light irradiation region X can be set on an appropriate position. Therefore, the resist 40 can be filled into the alignment marks 22a to 22d in a short period after the completion of the alignment.

As described above, according to the first embodiment, the UV light is irradiated to the alignment marks 22a to 22d and their surroundings during the alignment, which can prevent the resist 40 from going into (block the resist 40 from going into) the alignment marks 22a to 22d during the alignment. Accordingly, the alignment marks 22a to 22d can correctly be detected, whereby the alignment can correctly be carried out.

### Second Embodiment

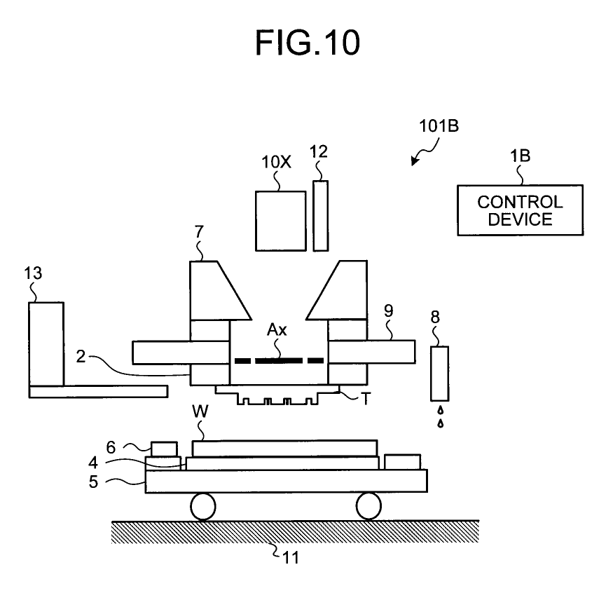

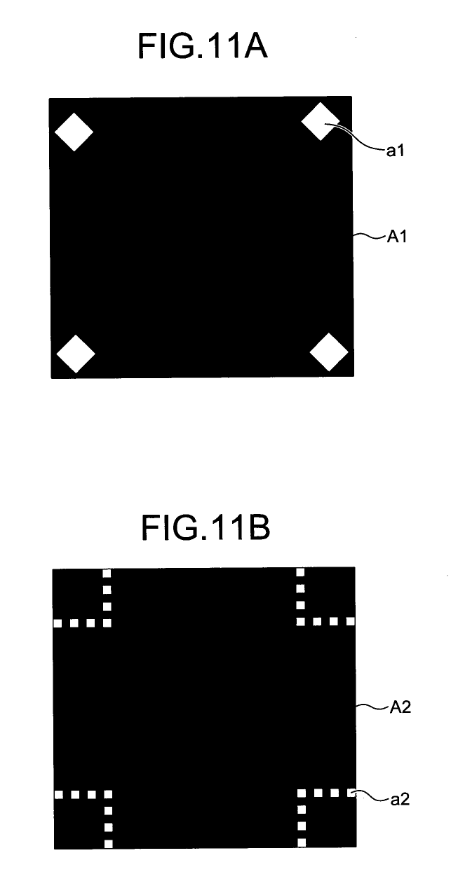

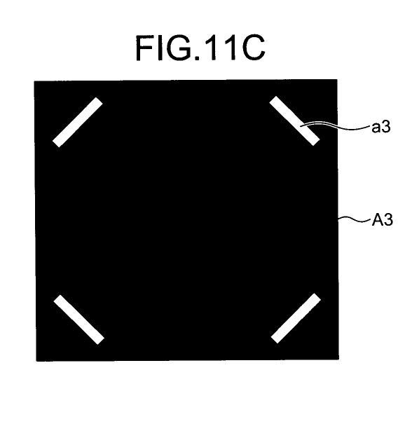

A second embodiment of the present invention will be described next with reference to FIG. 10 and FIGS. 11A to 11C. In the second embodiment, the UV light is irradiated to a desired UV light irradiation region X by use of an aperture during the alignment.

FIG. 10 is a view illustrating a configuration of an imprint apparatus according to the second embodiment. The components in FIG. 10 attaining the same functions as those in the imprint apparatus 101A in the first embodiment illustrated in FIG. 1 are identified by the same numerals, and the description will not be repeated.

An imprint apparatus 101B includes a control device 1B, an original plate stage 2, a substrate chuck 4, a sample stage 5, a reference mark 6, an alignment sensor 7, a liquid dropping device 8, a stage base 9, an UV light source 10X, a plate stage 11, a CCD (charge coupled device) camera 12, an original-plate conveyance arm 13, and an aperture Ax. In other words, the imprint apparatus 101B has the control device 1B instead of the control device 1A, and the aperture Ax instead of the UV light sources 10a to 10d, compared to the imprint apparatus 101A.

The aperture Ax is configured to be capable of moving between the UV light source 10X and a template T. The aperture Ax is formed of an almost plate-like member. It transmits some light of the UV light from the UV light source 10X, and shields the remaining light. On the aperture Ax according to the present embodiment, only a part of a major surface is open, for example, in order that the UV light is irradiated only to the light irradiation region X as described in the first embodiment.

During the alignment, the aperture Ax is arranged between the UV light source 10X and the template T, whereby the UV light is irradiated only to the UV light irradiation region X. After the filling of the resist 40 into the template pattern is finished, the aperture Ax is removed, and then, the UV light is irradiated to the whole surface of the template T from the UV light source 10X.

FIGS. 11A to 11C are views illustrating the structure of the aperture. FIGS. 11A to 11C are top views of apertures A1 to A3, which are examples of the aperture Ax. As illustrated in FIG. 11A, the aperture A1 has opening portions a1 in the vicinity of each of four corners.

As illustrated in FIG. 11B, the aperture A2 has plural opening portions a2 in the vicinity of four corners. As illustrated in FIG. 11C, the aperture A3 has line-type opening portions a3 in the vicinity of each of four corners.

When the UV light is irradiated through the aperture A1, the UV light passing through the opening portions a1 is irradiated onto the wafer W. Similarly, when the UV light is irradiated through the apertures A2 and A3, the UV light passing through the opening portions a2 and a3 is irradiated onto the wafer W. The region of the UV light irradiated from the opening portions a1 to a3 on the wafer W becomes the above-mentioned UV light irradiation region X.

As described above, according to the second embodiment, the UV light is irradiated to the alignment marks 22a to 22d and their surroundings by use of the aperture Ax during the alignment. This structure can prevent the resist 40 from going into the alignment marks 22a to 22d during the alignment. Since the aperture Ax is used, the UV light can be irradiated onto a desired position with a simple configuration. Accordingly, the alignment marks 22a to 22d can correctly be detected, whereby the alignment can correctly be carried out.

### Third Embodiment

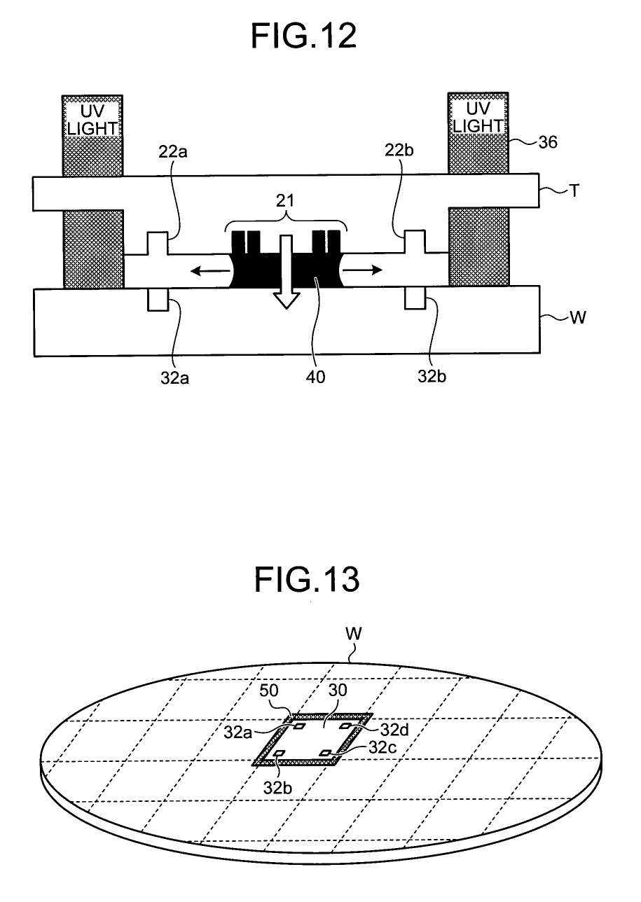

A third embodiment of the present invention will be described next with reference to FIGS. 12 and 13. In the third embodiment, the region outside the imprint shot is defined as the UV light irradiation region. The UV light is irradiated to the UV light irradiation region during the filling of the resist or during the alignment.

FIG. 12 is a view illustrating the UV light irradiation region according to the third embodiment. FIG. 12 illustrates an irradiation region of a UV light 36 in the imprint shot. FIG. 12 is a sectional view when the template T (wafer W) is cut along a line linking the alignment marks 22a and 22b (a line linking the alignment marks 32a and 32b). The components in FIG. 12 attaining the same functions as the functions of the template T or the wafer W in the first embodiment illustrated in FIG. 5A are identified by the same numerals, and the description will not be repeated.

As illustrated in FIG. 12, in the present embodiment, the UV light 36 is irradiated at the outside of the template pattern forming region 21 or the region (imprint shot) where the alignment marks 22a and 22b are formed during the imprint. In other words, the imprint is performed with the irradiation of the UV light 36 to the surrounding region (the outer perimeter around the template T) enclosing the imprint shot.

When the resist 40 is likely to move toward the outside of the imprint shot during the filling of the resist into the template pattern, this resist 40 is hardened between the imprint shots (boundary portion) by the UV light 36 in this process. Accordingly, the resist 40 does not protrude toward the outside of the region where the UV light 36 is irradiated.

FIG. 13 is a view illustrating the UV light irradiation region on the wafer. As illustrated in FIG. 13, an UV light irradiation region 50 in the present embodiment is the region (annular region) outside the imprint shot 30. When the imprint is performed on each imprint shot 30 on the wafer W, the UV light is irradiated to the UV light irradiation region of each of the imprint shots 30. Thus, the protrusion of the resist 40 on the imprint shot 30 can be prevented. Consequently, a desired resist pattern can be formed for each imprint shot.

The imprint (alignment or filling) with the irradiation of the UV light to the UV light irradiation region 50 is performed for each layer in a wafer process, for example. Specifically, after a film to be processed is formed on the wafer W, the resist 40 is applied onto the film to be processed. Then, the imprint is performed with the irradiation of the UV light to the UV light irradiation region on the wafer W onto which the resist 40 is applied, and then, the resist pattern is formed on the wafer W. The lower layer on the wafer W is etched with the resist pattern being used as a mask. With this process, an actual pattern corresponding to the template pattern is formed on the wafer W. When a semiconductor device (semiconductor integrated circuit) is manufactured, the above-mentioned film formation, imprint, and etching process are repeated for each layer.

According to the third embodiment, the UV light is irradiated to the surrounding region enclosing the imprint shot during the imprint. This structure can prevent the resist 40 from protruding toward the outside of the imprint shot.

According to the first to third embodiments, the UV light is irradiated to the region into which the resist 40 is not desired to go or its surrounding, whereby the resist 40 can be filled in a desired position.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint method comprising:
dropping a resist onto a substrate having a first alignment mark;
performing an alignment process between the first alignment mark and a second alignment mark, which is formed on a template, while filling the resist into a template pattern of the template by a press-contact of the template pattern to the resist on the substrate, so as to align the template to a predetermined position on the substrate;
irradiating light that hardens the resist onto a light irradiation region near the second alignment mark for hardening the resist in the light irradiation region, in order to prevent the resist from being filled in the second alignment mark during the alignment process,
filling the resist into the template pattern and the second alignment mark with the template being kept aligned on the predetermined position on the substrate, after the alignment process is completed; and
irradiating the light, which hardens the resist, onto the template.

2. The imprint method according to claim 1, wherein
the light irradiation region is a region where the resist is not dropped onto the substrate, and
the resist that is likely to go into the light irradiation region is hardened during the alignment process.

3. The imprint method according to claim 1, wherein
the light irradiation region is set based upon an imprint condition such that, until the alignment process is completed, the filling of the resist into the second alignment mark is inhibited, and after the alignment process is completed, the resist is filled into the second alignment mark.

4. The imprint method according to claim 1, wherein
an imprint condition is set based upon the light irradiation region such that, until the alignment process is completed, the filling of the resist into the second alignment mark is inhibited, and after the alignment process is completed, the resist is filled into the second alignment mark.

5. The imprint method according to claim 3, wherein
the imprint condition is at least one of a type of the resist, a drop amount of the resist, a drop position of the resist, viscosity of the resist, temperature of the resist, environment in an imprint apparatus, the position of the second alignment mark, a time taken for the alignment process, a time taken from the completion of the alignment process to the completion of resist filling, and press-contact force applied when the template pattern is pressed against the resist on the substrate.

6. The imprint method according to claim 4, wherein
the imprint condition is at least one of a type of the resist, a drop amount of the resist, a drop position of the resist, viscosity of the resist, temperature of the resist, environment in an imprint apparatus, the position of the second alignment mark, a time taken for the alignment process, a time taken from the completion of the alignment process to the completion of resist filling, and press-contact force applied when the template pattern is pressed against the resist on the substrate.

7. The imprint method according to claim 1, wherein
the light irradiation region is a region including at least a part of the second alignment mark.

8. The imprint method according to claim 1, wherein
the light irradiation region is a region between the second alignment mark and the resist dropped onto the substrate.

9. An imprint apparatus comprising:
a dropping unit configured to drop a resist onto a substrate having a first alignment mark;
an alignment process unit configured to perform an alignment process between the first alignment mark and a second alignment mark, which is formed on a template, while filling the resist into a template pattern of the template by a press-contact of the template pattern to the resist on the substrate, so as to align the template to a predetermined position on the substrate; and
a light irradiation unit configured to irradiate light that hardens the resist onto a light irradiation region near the second alignment mark for hardening the resist in the light irradiation region during the alignment process, in order to prevent the resist from being filled in the second alignment mark during the alignment process, and to irradiate the light that hardens the resist with the template being kept aligned on the predetermined position on the substrate and with the resist being filled in the template pattern and the second alignment mark, after the alignment process is completed.

10. The imprint apparatus according to claim 9, wherein
the light irradiation unit includes a first light irradiation unit that irradiates the light to the light irradiation region upon performing the alignment process, and
a second light irradiation unit that irradiates the light to the template after the alignment process is completed.

11. The imprint apparatus according to claim 9, further comprising an aperture that blocks light irradiated to a region other than the light irradiation region, wherein
the light irradiation unit irradiates the light to the light irradiation region through the aperture when the alignment process is performed, and
irradiates the light to the template not through the aperture after the alignment process is completed.

12. An imprint method comprising:
dropping a resist onto a substrate;
pressing a template pattern on a template against the resist on the substrate;
irradiating light, which hardens the resist, onto a light irradiation region outside an imprint shot so as to harden the resist that is likely to protrude toward the outside of the imprint shot, when the template pattern is pressed against the resist;
filling the resist into the template pattern with the template pattern being kept pressed against the resist; and
irradiating light that hardens the resist onto the template.

13. The imprint method according to claim 12, wherein
the light is irradiated to the light irradiation region so as to harden the resist that is likely to protrude to the outside of the imprint shot, when the resist is filled, or when the template is aligned to the substrate.

14. A manufacturing method of a semiconductor device comprising:
dropping a resist onto a substrate having a first alignment mark;
performing an alignment process between the first alignment mark and a second alignment mark, which is formed on a template, while filling the resist into a template pattern of the template by a press-contact of the template pattern to the resist on the substrate, so as to align the template to a predetermined position on the substrate;
irradiating light that hardens the resist onto a light irradiation region near the second alignment mark for hardening the resist in the light irradiation region, in order to prevent the resist from being filled in the second alignment mark during the alignment process,
filling the resist into the template pattern and the second alignment mark with the template being kept aligned on the predetermined position on the substrate, after the alignment process is completed;
irradiating the light, which hardens the resist, onto the template; and
processing the substrate from above of the hardened resist in order to form a substrate pattern, corresponding to the template pattern, onto the substrate.

15. The method for manufacturing a semiconductor device according to claim 14, wherein
the light irradiation region is a region where the resist is not dropped onto the substrate, and
the resist that is likely to go into the light irradiation region is hardened during the alignment process.

16. The method for manufacturing a semiconductor device according to claim 14, wherein
the light irradiation region is set based upon an imprint condition such that, until the alignment process is completed, the filling of the resist into the second alignment mark is inhibited, and after the alignment process is completed, the resist is filled into the second alignment mark.

17. The method for manufacturing a semiconductor device according to claim 14, wherein an imprint condition is set based upon the light irradiation region such that, until the alignment process is completed, the filling of the resist into the second alignment mark is inhibited, and after the alignment process is completed, the resist is filled into the second alignment mark.
